(19) United States
(12) Patent Application Publication
(10) Pub. No.: US 2025/0297900 A1
(43) Pub. Date: Sep. 25, 2025

(54) ESTIMATION APPARATUS, CURRENT SENSOR, SYSTEM, AND ESTIMATION METHOD

(71) Applicant: Asahi Kasei Microdevices Corporation, Tokyo (JP)

(72) Inventor: Kenji SUZUKI, Tokyo (JP)

(21) Appl. No.: 19/083,469

(22) Filed: Mar. 19, 2025

(30) Foreign Application Priority Data
Mar. 22, 2024 (JP) 2024-046006
Mar. 11, 2025 (JP) 2025-038778

(51) Int. Cl. G01K 7/42; G01R 15/20; H02M 1/32; H05K 1/02; H05K 1/11

(52) U.S. Cl. CPC G01K 7/425; G01R 15/205; H02M 1/327; H05K 1/0201; H05K 1/116; H05K 2201/10151

(57) ABSTRACT

An estimation apparatus includes: an estimation unit which estimates a temperature of a circuit board which includes a current sensor and a land portion in contact with a primary terminal of the current sensor and on which the current sensor is mounted, based on a predetermined coefficient which is based on at least one of a heat transfer characteristic between at least one magnetoelectric conversion element in the current sensor and the land portion or a heat transfer characteristic between a signal processing IC and the land portion in the circuit board, and at least one of: at least one of a current value or a voltage value of the at least one magnetoelectric conversion element; or at least one of a current value or a voltage value of the signal processing IC.

The contents of the following patent application(s) are incorporated herein by reference:
NO. 2024-046006 filed in JP on Mar. 22, 2024
NO. 2025-038778 filed in JP on Mar. 11, 2025.

### BACKGROUND

### 1. Technical Field

The present invention relates to an estimation apparatus, a current sensor, a system, and an estimation method.

### 2. Related Art

Patent Document 1 describes that overheating of a Hall element is detected by detecting a temperature of the Hall element. Patent Document 2 describes that even in a state where a temperature abnormality is not detected, when an abnormality in a power supply current is detected, power supply current supply to a high-frequency power amplifier is limited by a current limiting transistor. Patent Document 3 describes that heat dissipation failure of a semiconductor switch is determined based on a temperature difference between an internal temperature and an actual temperature estimated based on a current supplied to the semiconductor switch.

### PRIOR ART DOCUMENTS

### Patent Documents

Patent Document 1: Japanese Patent No. 6546884
Patent Document 2: Japanese Patent Application Publication No. H9-019048
Patent Document 3: Japanese Patent Application Publication No. 2023-009339

The summary clause does not necessarily describe all necessary features of the embodiments of the present invention. The present invention may also be a sub-combination of the features described above.

### BRIEF DESCRIPTION OF THE DRAWINGS

FIG. 1A is a schematic plan view illustrating a state where a current sensor is equipped on a circuit board as viewed from a ceiling surface side (Z axis direction) of the current sensor.

FIG. 1B is a cross-sectional view taken along line A-A of the circuit board on which the current sensor illustrated in FIG. 1A is equipped.

FIG. 2 is a plan view schematically illustrating an internal configuration of the current sensor.

FIG. 3 is a diagram illustrating an example of functional blocks of a system including an estimation apparatus that estimates a temperature of the circuit board.

FIG. 4A is a diagram illustrating an example of relationship information indicating a relationship between a resistance value of a magnetoelectric conversion element and a temperature of the magnetoelectric conversion element;

FIG. 4B is a diagram illustrating an example of relationship information indicating a relationship between a diode forward voltage (Si band gap voltage) in a signal processing IC and a temperature of the signal processing IC.

FIG. 5 is a flowchart illustrating an example of a procedure in which the estimation apparatus determines an abnormality in the temperature of the circuit board.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

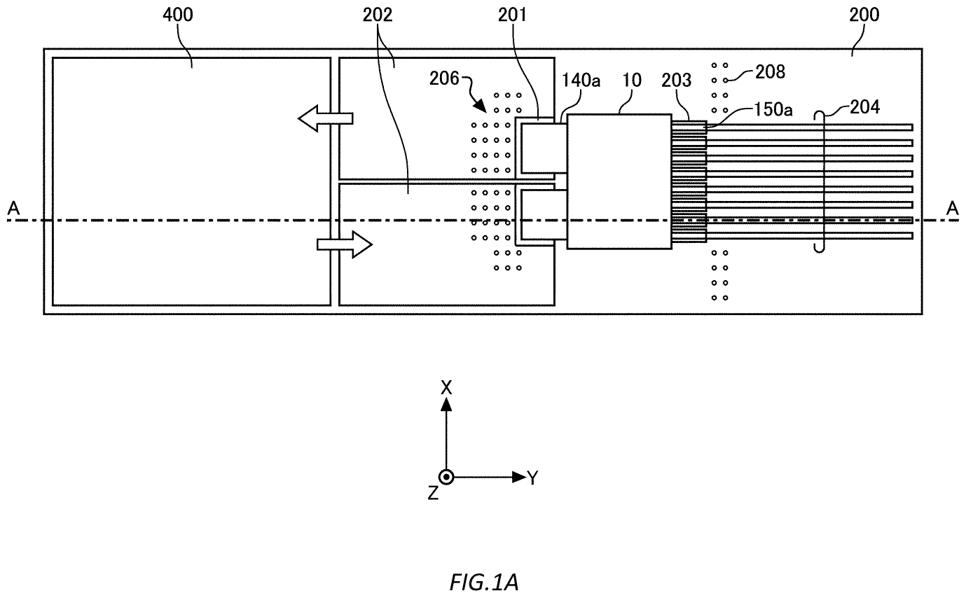

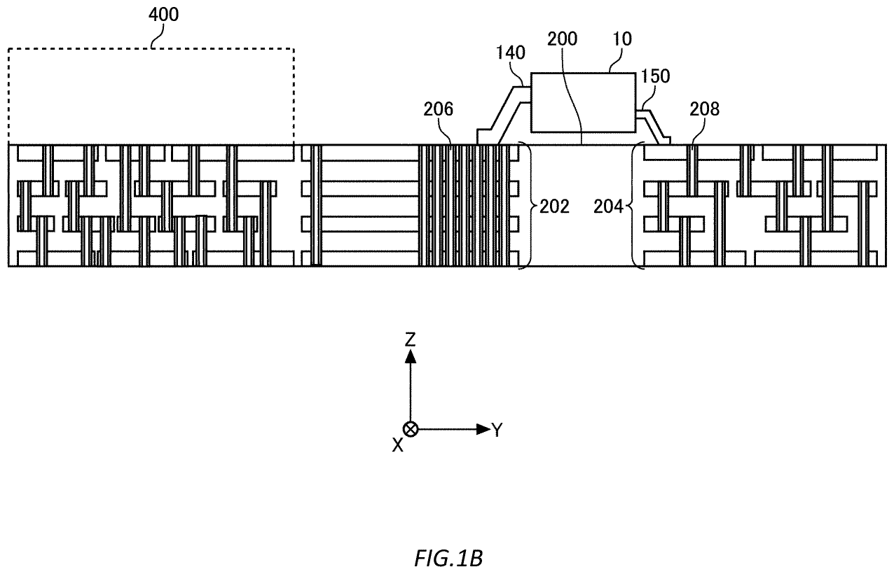

FIG. 1A is a schematic plan view illustrating a state where a current sensor 10 is equipped on a circuit board 200 as viewed from a ceiling surface side (Z axis direction) of the current sensor 10. FIG. 1B is a cross-sectional view taken along line A-A of the circuit board 200 on which the current sensor 10 illustrated in FIG. 1A is equipped.

Coordinates are defined in FIG. 1A such that a direction parallel to a plane of paper from bottom to top is an X axis direction, a direction parallel to the plane of the paper from left to right is a Y axis direction, and a direction perpendicular to the plane of the paper from back to front is the Z axis direction. Any one axis of an X axis, a Y axis, and a Z axis is orthogonal to the other axes. The Y axis direction is an example of a first direction. The X axis direction is an example of a second direction. The Z axis direction is an example of a thickness direction.

The current sensor 10 includes a primary terminal 140a through which a current to be measured flows, and a secondary terminal 150a which is used to input power to the current sensor 10 and output a processed signal.

The circuit board 200 includes a conductor layer 202 electrically connected to the primary terminal 140a through a land portion 201, and a conductor layer 204 electrically connected to the secondary terminal 150a through a land portion 203. The primary terminal 140a is soldered to the conductor layer 202 through the land portion 201. The secondary terminal 150a is soldered to the conductor layer 204 through the land portion 203. Even when the primary terminal 140a and the land portion 201 are connected via solder, it may be considered that the primary terminal 140a and the land portion 201 are in contact with each other. An electric circuit 400 such as an inverter is connected to the conductor layer 202, and a current from an electric machinery and apparatus is supplied to the primary terminal 140a through the conductor layer 202. Examples of the conductor layer 202 and the conductor layer 204 include a circuit board on which wiring is formed. The electric circuit 400 is an example of a load. The electric circuit 400 may be electrically connected to the conductor layer 202 through a conductor such as a cable. The electric circuit 400 may include an inverter circuit, and a connector or a terminal block for connecting from the inverter circuit to a motor or power supply equipment installed outside.

As illustrated in FIG. 1B, the conductor layer 202 and the conductor layer 204 are constituted by a plurality of layers, and the plurality of conductor layers 202 are electrically connected through a through-hole array 206 in which a plurality of through-holes are arranged in an array. The plurality of conductor layers 202 may be electrically connected through a plurality of vias. The plurality of conductor layers 204 may be electrically connected through a plurality of vias.

In the conductor layer 204 on a secondary terminal side, wiring or circuits between multilayer circuit boards are connected by a plurality of through-holes 208 for a general purpose of connecting the wiring or circuits between the multilayer circuit boards. Although through-holes are similarly provided also in the conductor layer 202 on a primary terminal side, a large number of through-holes or vias are preferably arranged in a concentrated manner like the through-hole array 206 in a region immediately below a land, which is a solder connection portion between the primary terminal and the circuit board, or in a vicinity of the land. That is, the plurality of through-holes constituting the through-hole array 206 may be densely arranged in a region near a connection portion between the land portion 201 and the primary terminal 140a. The region where the plurality of through-holes are densely arranged is a region where a number of at least one through-hole per unit area is greater than that of another region. By distributing heat, which is generated inside the current sensor 10, to multiple conductor layers 202 through a large number of through-holes or vias arranged immediately below the land or in the vicinity of the land, heat dissipation of the heat generated inside the current sensor 10 is improved, and currents flowing through the conductor layer of the circuit board are also quickly distributed to the multiple layers, so that an increase in a temperature of the circuit board caused by the current can also be suppressed to be low.

Each of the plurality of conductor layers 202 and the plurality of conductor layers 204 may be a metal layer, for example, a copper foil layer. For example, a diameter of each through-hole included in the through-hole array 206 may be 1.6 mm or less. An interval between the through-holes included in the through-hole array 206 may be 2 mm or less. The circuit board 200 may have, as the through-hole array 206, 20 or more through-holes immediately below the primary terminal 140a and within a circumference of 10 mm. An inside of each through-hole of the through-hole array 206 may be filled with solder.

In the current sensor 10 configured as described above, when a measurement current flowing to the primary terminal 140a through the electric circuit 400 is large, an internal temperature of the current sensor 10 increases through the primary terminal 140a, and thus it is conceivable to detect the internal temperature of the current sensor 10 and notify the temperature to outside. However, when the measurement current is large, there is a possibility that the circuit board 200 on which the current sensor 10 is equipped first reaches a limit in its allowable temperature before an internal element of the current sensor 10 reaches a limit in its allowable temperature, and a defect occurs in the circuit board 200. For example, an allowable temperature of a general IC manufactured using a Si wafer is about 150 degrees, an allowable temperature of a general magnetoelectric conversion element manufactured using a GaAs wafer is about 165 degrees, and an allowable temperature of a general FR4 circuit board manufactured using glass epoxy is about 130 degrees. Thus, there is a possibility that the temperature of the FR4 circuit board reaches its allowable temperature before the temperature of the IC or the magnetoelectric conversion element reaches its allowable temperature.

When the circuit board 200 is the FR4 circuit board and the current sensor 10 is surface-mounted on the circuit board 200, it is likely that the temperature of the circuit board first reaches its allowable temperature before the temperature of the IC or the magnetoelectric conversion element reaches its allowable temperature. In this case, the circuit board 200 may be a multilayer FR4 circuit board having a copper foil thickness of 70 μm or less and including a plurality of conductor layers.

On the other hand, when a temperature sensor is provided on the circuit board 200 in order to measure the temperature of the circuit board 200, it is necessary to secure a space for providing the temperature sensor on the circuit board 200. However, it may be difficult to secure an extra space in the circuit board 200. In addition, by adding the temperature sensor, a reliability is lowered and the cost is also increased as a number of at least one component is increased.

In this regard, in the present embodiment, without additionally adding a temperature sensor, the temperature of the circuit board 200 is estimated to sense an abnormality associated with an increase in the temperature of the circuit board 200.

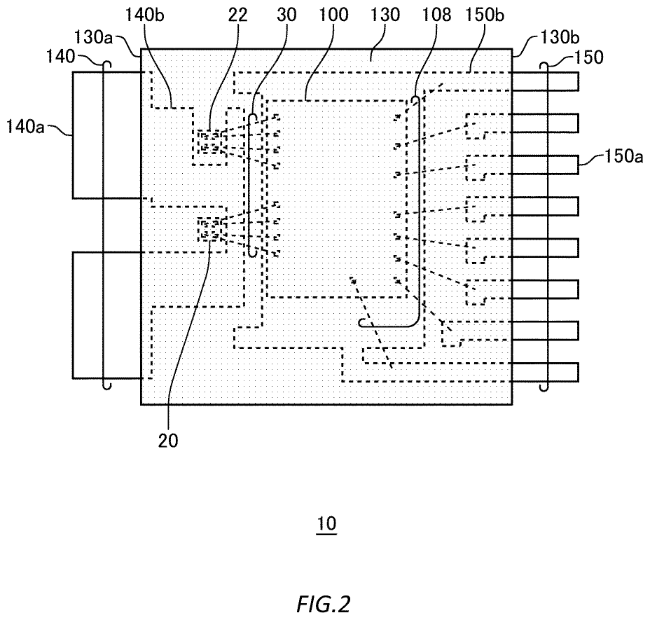

FIG. 2 is a plan view schematically illustrating an internal configuration of the current sensor 10. The current sensor 10 includes a signal processing IC 100, a magnetoelectric conversion element 20, a magnetoelectric conversion element 22, a sealing portion 130, a lead frame 140, and a lead frame 150. The magnetoelectric conversion element 20 and the magnetoelectric conversion element 22 are electrically connected to the signal processing IC 100 through a wire 30. The signal processing IC 100 is electrically connected to the lead frame 150 through a wire 108. The wire 30 is an example of a first wire, and the wire 108 is an example of a second wire. The current sensor 10 is an example of a surface-mount type semiconductor package.

The lead frame 140 includes a pair of the primary terminals 140a protruding from a side surface 130a of the sealing portion 130, and a primary conductor 140b sealed by the sealing portion 130 and arranged so as to surround at least a part of the magnetoelectric conversion element 20 and the magnetoelectric conversion element 22. The lead frame 150 includes a plurality of the secondary terminals 150a protruding from a side surface 130b opposed to the side surface 130a of the sealing portion 130 in the Y axis direction, and a secondary conductor 150b electrically connected to the signal processing IC 100 through the wire 108.

The lead frame 140 has a U-shaped portion in plan view such that a measurement current input from one of the pair of primary terminals 140a is output from another of the pair of primary terminals 140a. The magnetoelectric conversion element 20 is arranged inside the U-shaped portion. The magnetoelectric conversion element 22 is arranged outside the U-shaped portion. Shapes of the lead frame 140 and the lead frame 150 illustrated in FIG. 1A are merely examples, and the shapes of the lead frame 140 and the lead frame 150 may be any shapes.

The lead frame 140 is physically separated from and electrically insulated from the lead frame 150. The lead frame 140 and the lead frame 150 are electrically insulated with a withstand voltage of 480 V or more. The primary terminal 140a is electrically connected to a high-voltage power supply system. The secondary terminal 150a is electrically connected to a low-voltage power supply system which applies a voltage lower than that of the high-voltage power supply system.

The sealing portion 130 seals the magnetoelectric conversion element 20, the magnetoelectric conversion element 22, the primary conductor 140b, the secondary conductor 150b, the signal processing IC 100, the wire 30, and the wire 108 with a mold resin. The sealing portion 130 may be formed by compression molding, transfer molding, or the like using a mold. The mold resin may be, for example, an epoxy-based thermosetting resin with added silica. The mold resin may be a thermoplastic resin such as a liquid crystal polymer.

The magnetoelectric conversion elements 20 and 22 detect a magnetic field in a specific direction that changes in accordance with a measurement current flowing through the primary conductor 140b, and the signal processing IC 100 inputs a signal proportional to a magnitude of the magnetic field, cancels external magnetic noise by taking a difference between the magnetoelectric conversion elements 20 and 22, amplifies the signal at a desired gain, and then outputs the amplified signal through the lead frame 150. The magnetoelectric conversion elements 20 and 22 each are an example of an element that outputs a signal corresponding to a current flowing through the lead frame 140. The magnetoelectric conversion elements 20 and 22 are composed of a compound semiconductor formed on a GaAs circuit board, and are chips cut out in a square or rectangular shape in plan view from the Z axis direction.

When a magnetic field in the Z axis direction is detected, the magnetoelectric conversion elements 20 and 22 may be Hall elements. When a magnetic field in any one axial direction of an XY plane is detected, the magnetoelectric conversion elements 20 and 22 may be magnetoresistive elements such as an AMR sensor, a TMR sensor, or a GMR sensor, or flux gate elements. When the magnetoelectric conversion elements 20 and 22 are magnetoresistive elements, the magnetoelectric conversion element 20 may be arranged at a position facing a portion where one lead terminal of the U-shaped portion of the lead frame 140 is connected, and the magnetoelectric conversion element 22 may be arranged at a position facing a portion where another lead terminal of the U-shaped portion of the lead frame 140 is connected.

The signal processing IC 100 is a large-scale integrated circuit (LSI). The signal processing IC 100 is a signal processing circuit and a bias circuit composed of a Si monolithic semiconductor formed on a Si circuit board. The bias circuit applies a corrected drive current or drive voltage to the magnetoelectric conversion elements 20 and 22. The signal processing circuit processes output signals corresponding to magnitudes of the magnetic field output from the magnetoelectric conversion elements 20 and 22. The signal processing circuit corrects the measurement current flowing through the lead frame 140, based on the output signals, and outputs, through the secondary terminal 150a, an output signal indicating an accurate current value. The signal processing circuit reduces a noise component included in the output signal of the magnetoelectric conversion element 20 and the output signal of the magnetoelectric conversion element 22, based on a difference between the output signal of the magnetoelectric conversion element 20 and the output signal of the magnetoelectric conversion element 22, amplifies the output signal of the magnetoelectric conversion element 20 and the output signal of the magnetoelectric conversion element 22 in which the noise component is reduced, calculates a current value of the measurement current, based on the amplified output signals, and outputs an output signal indicating the current value.

In the present embodiment, an example will be described in which the current sensor 10 includes two magnetoelectric conversion elements, but the current sensor 10 is only required to include at least one magnetoelectric conversion element. In addition, in the present embodiment, an example will be described in which the magnetoelectric conversion elements 20 and 22 are chips independent of the signal processing IC 100. However, the magnetoelectric conversion elements 20 and 22 may be silicon-monolithic magnetoelectric conversion elements built in the signal processing IC 100.

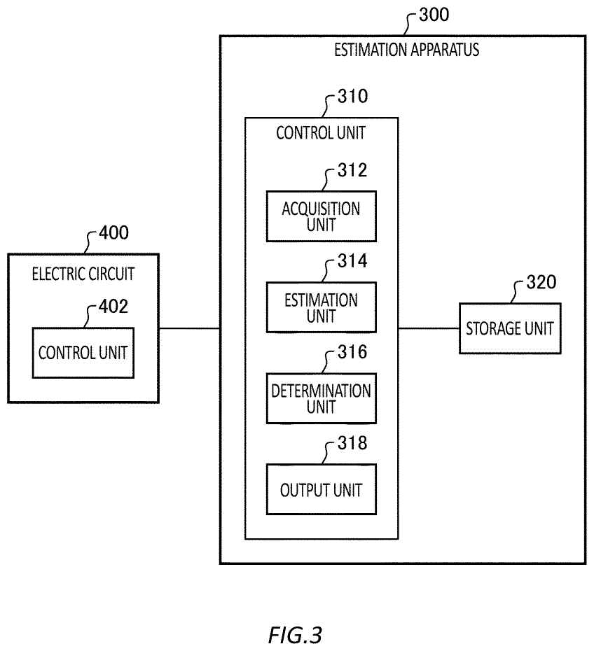

FIG. 3 is an example of functional blocks of a system including an estimation apparatus 300 that estimates the temperature of the circuit board 200.

The estimation apparatus 300 includes a control unit 310 and a storage unit 320. The control unit 310 may is constituted by a microprocessor such as a CPU or an MPU, a microcontroller such as an MCU, or the like. The signal processing IC 100 may function as the estimation apparatus 300. The storage unit 320 stores information necessary for the estimation apparatus 300 to estimate the temperature of the circuit board 200 on which the current sensor 10 is mounted. The estimation apparatus 300 may be provided in an apparatus which can communicate with the current sensor 10 and is different from the current sensor 10. The estimation apparatus 300 is communicably connected to the electric circuit 400 which receives a measurement current measured by the current sensor 10 or outputs the measurement current. The electric circuit 400 includes a control unit 402 constituted by a processor or the like which controls an operation of the electric circuit 400.

The control unit 310 includes an acquisition unit 312, an estimation unit 314, a determination unit 316, and an output unit 318. The acquisition unit 312 acquires a current value Ia of the current flowing through the primary conductor 140b. The acquisition unit 312 may acquire a current value derived by the above-described signal processing circuit, as the current value I flowing through the primary conductor 140b.

The acquisition unit 312 acquires current values Ib of the currents output from the magnetoelectric conversion element 20 and the magnetoelectric conversion element 22 and voltage values Vb of the voltages applied to the magnetoelectric conversion element 20 and the magnetoelectric conversion element 22. The acquisition unit 312 may acquire the current values Ib of the currents output from the magnetoelectric conversion element 20 and the magnetoelectric conversion element 22 and the voltage values Vb of the voltages applied to the magnetoelectric conversion element 20 and the magnetoelectric conversion element 22, from control information of the signal processing IC 100 which controls power supplied to the magnetoelectric conversion element 20 and the magnetoelectric conversion element 22.

The acquisition unit 312 acquires a current value Ic of the current and a voltage value Vc of the voltage input to the signal processing IC 100. The acquisition unit 312 may acquire the current value Ic and the voltage value Vc from a reference voltage source built in the signal processing IC 100.

The estimation unit 314 may estimate the temperature of the circuit board 200, based on a predetermined coefficient which is based on at least one of a heat transfer characteristic between each of the magnetoelectric conversion elements 20 and 22 and the primary conductor 140b or a heat transfer characteristic between the signal processing IC 100 and the primary conductor 140b, and at least one of the current value Ib and the voltage value Vb of each of the magnetoelectric conversion elements 20 and 22 or the current value Ic and the voltage value Vc of the signal processing IC 100. The predetermined coefficient which is based on at least one of the heat transfer characteristic between each of the magnetoelectric conversion elements 20 and 22 and the primary conductor 140b or the heat transfer characteristic between the signal processing IC 100 and the primary conductor 140b may be determined based on a relationship ΔT1 (described later) between temperatures of the magnetoelectric conversion elements 20 and 22 and the signal processing IC 100 and a temperature of the primary terminal 140a.

The estimation unit 314 may estimate the temperature of the circuit board 200, based on a predetermined coefficient which is based on at least one of a heat transfer characteristic between each of the magnetoelectric conversion elements 20 and 22 and the land portion 201 or a heat transfer characteristic between the signal processing IC 100 and the land portion 201, and at least one of the current value Ib and the voltage value Vb of each of the magnetoelectric conversion elements 20 and 22, or the current value Ic and the voltage value Vc of the signal processing IC 100. The predetermined coefficient which is based on at least one of the heat transfer characteristic between each of the magnetoelectric conversion elements 20 and 22 and the land portion 201 or the heat transfer characteristic between the signal processing IC 100 and the land portion 201 may be determined based on the relationship ΔT1 between the temperatures of the magnetoelectric conversion elements 20 and 22 and the signal processing IC 100 and the temperature of the primary terminal 140a and a relationship ΔT2 between a temperature of the primary conductor 140b and a temperature of the land portion 201 connected to the primary terminal 140a.

The estimation unit 314 may estimate, as the temperature of the circuit board 200, the temperature of the land portion 201, which is in contact with the primary terminal 140a, of the circuit board 200. The estimation unit 314 may consider the temperature of the land portion 201 in contact with the primary terminal 140a via solder, as the temperature of the land portion 201, which is in contact with the primary terminal 140a, of the circuit board 200, and estimate the temperature of the land portion 201 as the temperature of the circuit board 200.

The heat transfer characteristic between each of the magnetoelectric conversion elements 20 and 22 and the primary conductor 140b is determined in advance based on at least one of a distance between each of the magnetoelectric conversion elements 20 and 22 and the primary conductor 140b or a thermal conductivity of a material constituting the sealing portion 130, that is, the mold resin.

The heat transfer characteristic between the signal processing IC 100 and the primary conductor 140b is determined in advance based on at least one of a distance between the signal processing IC 100 and the primary conductor 140b or the thermal conductivity of the material constituting the sealing portion 130.

Here, the relationship ΔT1 between the temperatures of the magnetoelectric conversion elements 20 and 22 and the signal processing IC 100 and the temperature of the primary terminal 140a depends on a heat transfer function of the mold resin existing between the magnetoelectric conversion elements 20 and 22 and the signal processing IC 100, and the primary conductor 140a. In addition, the relationship ΔT1 also depends on an arrangement relationship between the magnetoelectric conversion elements 20 and 22 and the signal processing IC 100, which are sealed in the sealing portion 130, and the primary conductor 140b, and a material and a shape of the primary conductor 140b. In addition, when a heat dissipation member such as a heat dissipation fin is attached to the current sensor 10, the relationship ΔT1 between the temperatures of the magnetoelectric conversion elements 20 and 22 and the signal processing IC 100 and the temperature of the primary terminal 140a also depends on a heat transfer function of the heat dissipation member.

The relationship ΔT2 between the temperature of the primary conductor 140b and the temperature of the land portion 201 connected to the primary terminal 140a depends on the material and the shape of the primary terminal 140a and a type of solder constituting the land portion 201, that is, a thermal conductivity of the solder and the thickness of a solder layer. In addition, ΔT2 also depends on a thermal conductivity determined by a width, a thickness, a number of at least one layer, or the like of a copper foil serving as a current wiring route in the circuit board 200, with respect to a distance from the land portion 201 to a load circuit on the circuit board 200 or a current lead-out cable. In addition, when forced cooling is performed from an outside of the current sensor 10 and the circuit board 200, ΔT2 also depends on a cooling effect.

A relationship ΔT3 between the temperature of the land portion 201 and a temperature of any other location of the circuit board 200 depends on the thermal conductivity of the circuit board 200 depending on the width or the thickness of the copper foil of the circuit board 200, the number of at least one layer of the copper foil, or the like, a distance to the circuit configured on the circuit board 200, a distance to the current lead-out cable, or the like.

Therefore, the heat transfer characteristic between each of the magnetoelectric conversion elements 20 and 22 and any location of the circuit board 200 depends on the relationship ΔT1, the relationship 42, and the relationship ΔT3. In consideration of these, a coefficient for deriving the temperature of the circuit board 200 from the temperature of each of the magnetoelectric conversion elements 20 and 22, and a coefficient for deriving the temperature of the circuit board 200 from the temperature of the signal processing IC 100 may be determined in advance based on experimental results or the like.

For example, when the estimation unit 314 estimates the temperature of the land portion 201 of the circuit board 200 as the temperature of the circuit board 200, the heat transfer characteristic is estimated based on the relationship ΔT1 and the relationship ΔT2, and when the estimation unit 314 estimates the temperature of any other location of the circuit board 200, an average value of the temperatures of the circuit board, or the like as the temperature of the circuit board 200, the heat transfer characteristic is estimated based on the relationship ΔT1, the relationship ΔT2, and the relationship ΔT3.

The estimation unit 314 of the current sensor 10 may derive a resistance value Rb of each of the magnetoelectric conversion elements 20 and 22 from the current value Ib and the voltage value Vb of each of the magnetoelectric conversion elements 20 and 22, and estimate the temperature of each of the magnetoelectric conversion elements 20 and 22, based on relationship information indicating a relationship between the resistance values of the magnetoelectric conversion elements 20 and 22 and the temperatures of the magnetoelectric conversion elements 20 and 22, and the derived resistance value Rb. Furthermore, the estimation unit 314 may multiply respective estimated temperatures T1 and T2 of the magnetoelectric conversion elements 20 and 22 by the predetermined coefficient, and estimate the temperature of the circuit board 200 based on the obtained temperatures. The estimation unit 314 may estimate, as the temperature of the circuit board 200, an average value of two temperatures derived by multiplying the respective estimated temperatures of the magnetoelectric conversion elements 20 and 22 by the predetermined coefficient, or a higher temperature of the two temperatures.

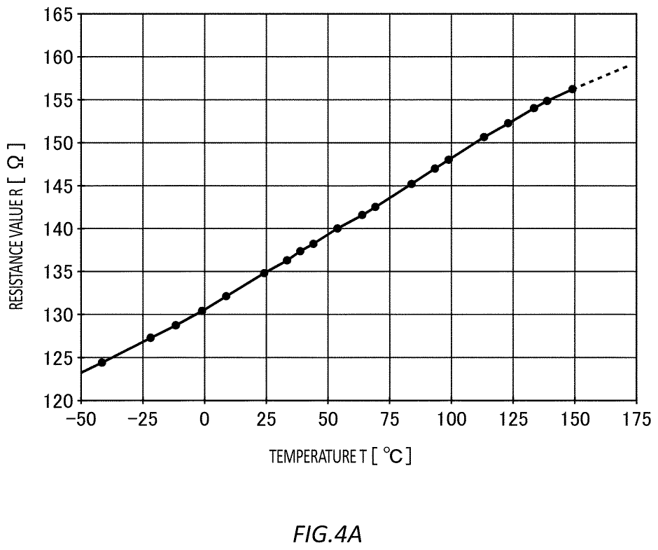

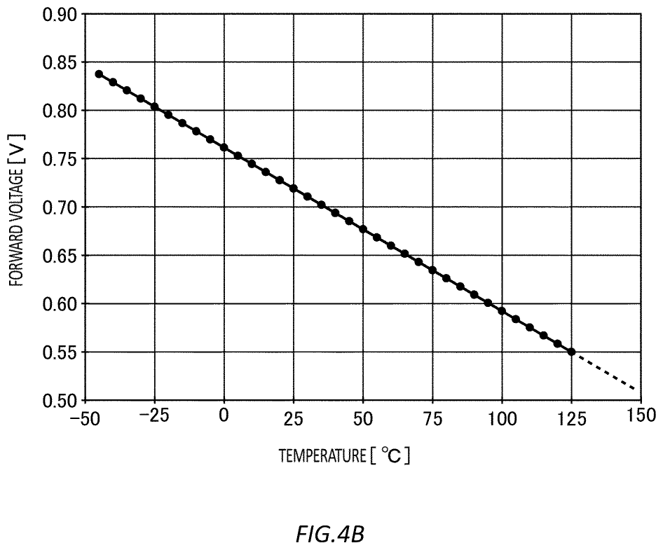

FIG. 4A is an example of the relationship information indicating the relationship between the resistance values of the magnetoelectric conversion elements 20 and 22 and the temperatures of the magnetoelectric conversion elements 20 and 22. The estimation unit 314 may acquire the temperatures T1 and T2 of the magnetoelectric conversion elements 20 and 22, based on the resistance values Rb of the magnetoelectric conversion element 20 and the magnetoelectric conversion element 22 and the relationship information as illustrated in FIG. 4A. The acquisition unit 312 may derive resistance values R1 and R2 of the magnetoelectric conversion elements 20 and 22, based on the voltage values Vb of the voltages applied to the magnetoelectric conversion elements 20 and 22 and the current values Ib of the currents output from the secondary terminals 150a of the magnetoelectric conversion elements 20 and 22.

FIG. 4B is an example of relationship information indicating a relationship between a forward voltage of a Si diode and the temperature of the signal processing IC 100. The estimation unit 314 may estimate the temperature of the signal processing IC 100, based on relationship information indicating a relationship between a voltage value of a voltage of the reference voltage source of the signal processing IC 100, that is, a band gap voltage value (the forward voltage of the Si diode) and the temperature of the signal processing IC 100, and the voltage value Vc acquired from the reference voltage source. Furthermore, the estimation unit 314 may estimate the temperature of the circuit board 200 by multiplying the estimated temperature of the signal processing IC 100 by the predetermined coefficient.

The estimation unit 314 may estimate the temperature of the circuit board 200, based on the temperatures of the circuit board 200 estimated from the resistance values of the magnetoelectric conversion elements 20 and 22, respectively, and the temperature of the circuit board 200 estimated from the band gap voltage of the signal processing IC 100. The estimation unit 314 may estimate, as the temperature of the circuit board 200, an average value or a maximum value of the temperatures of the circuit board 200 estimated from the resistance values of the magnetoelectric conversion elements 20 and 22, respectively, and the temperature of the circuit board 200 estimated from the band gap voltage of the signal processing IC 100. Since there is a tendency that a portion, which in contact with the primary terminal 140a, among components mounted on the circuit board 200 generates a largest amount of heat inside the current sensor 10, it can be said that the land portion 201 in contact with the primary terminal 140a is a portion having a highest temperature in the circuit board. That is, when the estimation unit 314 estimates the maximum value of the temperature of the circuit board 200 as an estimation value of the temperature of the circuit board 200, for example, it may be assumed that the maximum value of the temperature of the circuit board 200 is the temperature of the land portion 201.

When the temperature of the circuit board 200 does not satisfy a predetermined temperature condition, the determination unit 316 determines that an abnormality in the temperature of the circuit board 200 has occurred. When the temperature of the circuit board 200 exceeds a first threshold TH1, the determination unit 316 may determine that the increase in the temperature of the circuit board 200 is to be suppressed. When the temperature of the circuit board 200 exceeds the first threshold TH1, the determination unit 316 may determine that an alert signal indicating that the temperature of the circuit board 200 exceeds the first threshold TH1 is to be output, may determine that power consumed in the electric circuit 400 is to be suppressed, may determine that the electric circuit 400 is to be operated in a power saving mode, or may determine that the circuit board 200 is to be cooled. When the temperature of the circuit board 200 exceeds a second threshold TH2 which is higher than the first threshold TH1, the determination unit 316 may determine that the operation of the electric circuit 400 is to be stopped.

In a case where the electric circuit 400 includes the inverter circuit which supplies power to the motor, when the temperature of the circuit board 200 exceeds the first threshold TH1, the determination unit 316 may determine that the inverter circuit is to be operated to operate the motor in the power saving mode. When the temperature of the circuit board 200 exceeds the second threshold TH2, the determination unit 316 may determine that the motor is to be stopped.

When the current value Ia of the current flowing through the primary conductor 140b exceeds a predetermined threshold THa, the determination unit 316 may determine that an overcurrent is flowing through the primary conductor 140b.

When a result of the determination by the determination unit 316 shows that the temperature of the circuit board 200 exceeds the first threshold TH1, the output unit 318 may output, to the control unit 402 which controls the electric circuit 400, a signal indicating that the temperature of the circuit board 200 exceeds the first threshold TH1. When the temperature of the circuit board 200 exceeds the second threshold TH2, the output unit 318 may output, to the control unit 402, a signal indicating that the temperature of the circuit board 200 exceeds the second threshold TH2.

When the result of the determination by the determination unit 316 shows that the temperature of the circuit board 200 exceeds the first threshold TH1, the output unit 318 may output, to the control unit 402, a signal including an instruction to suppress the power consumed in the electric circuit 400. When the temperature of the circuit board 200 exceeds the second threshold TH2, the output unit 318 may output, to the control unit 402, a signal including an instruction to stop the operation of the electric circuit 400.

When the result of the determination by the determination unit 316 shows that the temperature of the circuit board 200 exceeds the first threshold TH1, the output unit 318 may output, to the control unit 402, at least one of the signal including the instruction to suppress the power consumed in the electric circuit 400, the alert signal indicating that the temperature of the circuit board 200 exceeds the first threshold TH1, or a signal including an instruction to cool the circuit board 200.

Examples of a means for cooling the circuit board 200 include increasing a rotation speed of a cooling fan installed near the circuit board 200, circulating a coolant flowing in a pipe of a water-cooled heat sink installed near the circuit board 200 while cooling the coolant or increasing a circulation speed of the coolant, increasing a current to a Peltier element installed near the circuit board 200, increasing a blowing amount of the air blown by a compressor installed near the circuit board 200 or decreasing a blowing temperature, and the like.

When the current value Ia of the current flowing through the primary conductor 140b exceeds the predetermined threshold THa, the output unit 318 may output, to the control unit 402, a signal indicating that an overcurrent is flowing through the primary conductor 140b.

Here, the temperature of the magnetoelectric conversion element 20 or the magnetoelectric conversion element 22, or the signal processing IC 100 may rapidly change due to an abnormality in the magnetoelectric conversion element 20 or the magnetoelectric conversion element 22, or the signal processing IC 100. In this case, there is a possibility that, before the heat reaches the circuit board 200, the temperature of the magnetoelectric conversion element 20 or the magnetoelectric conversion element 22, or the signal processing IC 100 reaches its allowable temperature. In such a case, an accuracy of the temperature of the circuit board 200 estimated from the temperature of the magnetoelectric conversion element 20 or the magnetoelectric conversion element 22, or the signal processing IC 100 is low, and it is preferable that the determination unit 316 does not determine the abnormality in the temperature of the circuit board 200. In such a case, it is preferable that the determination unit 316 determines the abnormality in the magnetoelectric conversion element 20 or the magnetoelectric conversion element 22, or the signal processing IC 100. In this regard, when a rate of change in the temperature, which is estimated, of the circuit board 200 is higher than a predetermined rate of change, the determination unit 316 may determine that the abnormality in the magnetoelectric conversion element 20 or the magnetoelectric conversion element 22, or the signal processing IC 100 has occurred, and in particular, even when the estimated temperature of the circuit board does not satisfy the predetermined temperature condition, the determination unit 316 may determine that the abnormality in the magnetoelectric conversion element 20 or the magnetoelectric conversion element 22, or the signal processing IC 100 has occurred, instead of the abnormality in the temperature of the circuit board 200.

When the estimated temperature of the magnetoelectric conversion element 20 or the magnetoelectric conversion element 22, or the signal processing IC 100 is higher than a predetermined temperature, the determination unit 316 may determine that the abnormality in the magnetoelectric conversion element 20 or the magnetoelectric conversion element 22, or the signal processing IC 100 has occurred, and in particular, even when the estimated temperature of the circuit board 200 does not satisfy the predetermined temperature condition, the determination unit 316 may determine that the abnormality in the magnetoelectric conversion element 20 or the magnetoelectric conversion element 22, or the signal processing IC 100 has occurred, instead of the abnormality in the temperature of the circuit board 200.

Even when receiving, from the determination unit 316, the signal indicating that the overcurrent is flowing through the primary conductor 140b, the output unit 318 may stop a current flowing from the electric circuit 400 to the primary conductor 140b of the current sensor 10 and transmit the fact that the overcurrent has occurred. The estimation apparatus 300 may notify a display or the like of an alarm message corresponding to a type of the signal. A control apparatus may register, as a log in a memory, contents of the signal, that is, alarm contents indicating the occurrence of the abnormality in the temperature of the circuit board 200, the abnormality in the magnetoelectric conversion element 20 or the magnetoelectric conversion element 22, the abnormality in the signal processing IC 100, or the inflow of the overcurrent to the current sensor 10.

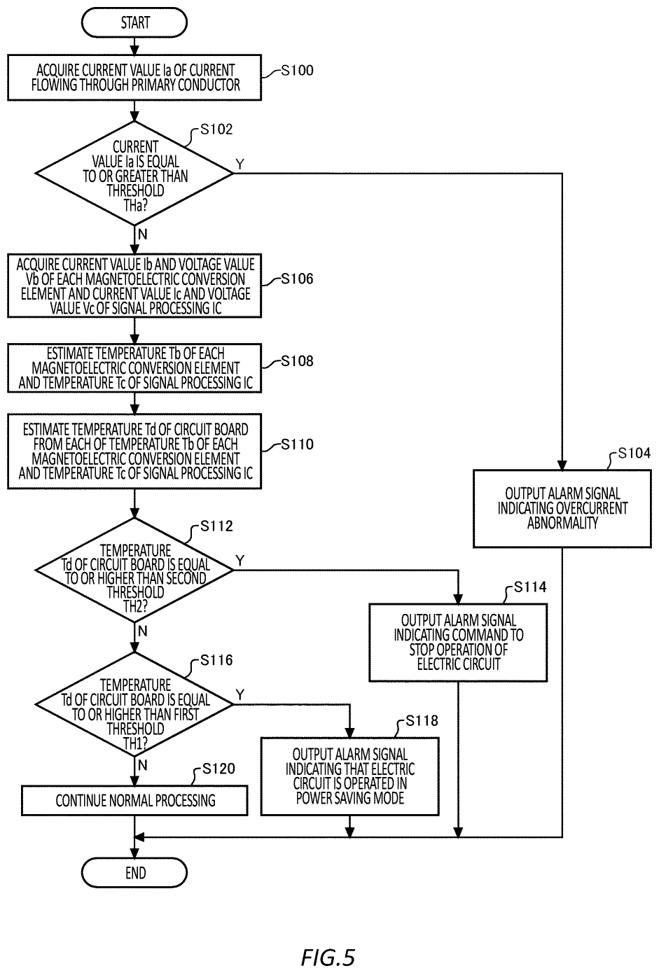

FIG. 5 is a flowchart illustrating an example of a procedure in which the estimation apparatus 300 determines the abnormality in the temperature of the circuit board 200.

The acquisition unit 312 acquires the current value Ia of the current flowing through the primary conductor 140b (S100). The acquisition unit 312 may acquire the current value derived by the signal processing circuit included in the signal processing IC 100, as the current value Ia flowing through the primary conductor 140b. The determination unit 316 determines whether or not the current value Ia is equal to or greater than the threshold THa (S102).

If the current value Ia is equal to or larger than the threshold THa, the output unit 318 outputs an alarm signal indicating an overcurrent abnormality in which the overcurrent is flowing through the current sensor 10 (S104). On the other hand, if the current value Ia is less than the threshold THa, the acquisition unit 312 acquires the current values Ib of the currents output from the magnetoelectric conversion elements 20 and 22, the voltage values Vb of the voltages applied to the magnetoelectric conversion elements 20 and 22, and the current value Ic of the current and the voltage value Vc of the voltage input to the signal processing IC 100 (S106). The acquisition unit 312 may acquire the current values Ib of the currents output from the magnetoelectric conversion element 20 and the magnetoelectric conversion element 22 and the voltage values Vb of the voltages applied to the magnetoelectric conversion element 20 and the magnetoelectric conversion element 22, from the control information of the signal processing IC 100 that controls the power supplied to the magnetoelectric conversion element 20 and the magnetoelectric conversion element 22. The acquisition unit 312 may acquire the current value Ic and the voltage value Vc from the reference voltage source built in the signal processing IC 100.

The estimation unit 314 estimates temperatures Tb of the magnetoelectric conversion elements 20 and 22 and a temperature Tc of the signal processing IC 100, based on at least one of the current values Ib or the voltage values Vb of the magnetoelectric conversion elements 20 and 22 and at least one of the current value Ic or the voltage value Vc of the signal processing IC (S108). The estimation unit 314 may derive the resistance value Rb of each of the magnetoelectric conversion elements 20 and 22 from the current value Ib and the voltage value Vb of each of the magnetoelectric conversion elements 20 and 22, and estimate the temperature Tb of each of the magnetoelectric conversion elements 20 and 22, based on the relationship information indicating the relationship between the resistance values of the magnetoelectric conversion elements 20 and 22 and the temperatures of the magnetoelectric conversion elements 20 and 22, and the derived resistance value Rb. The estimation unit 314 may estimate the temperature Tc of the signal processing IC 100, based on the relationship information indicating the relationship between the voltage value of the voltage of the reference voltage source of the signal processing IC 100 and the temperature of the signal processing IC 100, and the voltage value Vc acquired from the reference voltage source.

The estimation unit 314 estimates a temperature Td of the circuit board 200 from each of the temperatures Tb of the magnetoelectric conversion elements 20 and 22 and the temperature Tc of the signal processing IC 100 (S110). The estimation unit 314 may estimate, as the temperature Td of the circuit board 200, an average value or a maximum value of the temperatures of the circuit board 200 estimated from the temperatures Tb of the magnetoelectric conversion elements 20 and 22, respectively, and the temperature of the circuit board 200 estimated from the temperature Tc of the signal processing IC 100.

The determination unit 316 determines whether or not the temperature Td of the circuit board 200 is equal to or higher than the second threshold TH2 (S112). If the temperature Td of the circuit board 200 is equal to or higher than the second threshold TH2, the output unit 318 outputs an alarm signal indicating a command to stop the operation of the electric circuit 400 (S114).

If the temperature Td of the circuit board 200 is lower than the second threshold TH2, the determination unit 316 determines whether or not the temperature Td of the circuit board 200 is equal to or higher than the first threshold TH1 (S116). If the temperature Td of the circuit board 200 is equal to or higher than the first threshold TH1, the output unit 318 outputs an alarm signal indicating that the electric circuit 400 is operated in the power saving mode (S118).

If the temperature Td of the circuit board 200 is lower than the first threshold TH1, the determination unit 316 determines that no abnormality has occurred in the temperature of the current sensor 10 and the temperature of the circuit board 200, and the output unit 318 does not output the alarm signal and causes the electric circuit 400 to continue normal processing (S120).

As described above, according to the estimation apparatus 300 according to the present embodiment, even when the measurement current measured by the current sensor 10 is large, it is possible to suppress that the circuit board 200 on which the current sensor 10 is equipped first reaches the limit in its allowable temperature before the internal element of the current sensor 10 reaches the limit in its allowable temperature, and a defect occurs in the circuit board 200.

While the embodiments of the present invention have been described, the technical scope of the invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### (Item 1)

An estimation apparatus including:
an acquisition unit which acquires at least one of: at least one of a current value of a current output from at least one magnetoelectric conversion element or a voltage value of a voltage applied to the at least one magnetoelectric conversion element; or at least one of a current value of a current or a voltage value of a voltage input to a signal processing IC, in a current sensor including the at least one magnetoelectric conversion element, a primary conductor through which a measurement current measured by the at least one magnetoelectric conversion element flows, and a primary terminal which is electrically connected to the primary conductor, the signal processing IC which processes a signal output from the at least one magnetoelectric conversion element, and a sealing portion which seals the at least one magnetoelectric conversion element, the primary conductor, and the signal processing IC; and
an estimation unit which estimates a temperature of a circuit board which includes the current sensor and a land portion in contact with the primary terminal of the current sensor and on which the current sensor is mounted, based on a predetermined coefficient which is based on at least one of a heat transfer characteristic between the at least one magnetoelectric conversion element and the land portion or a heat transfer characteristic between the signal processing IC and the land portion in the circuit board, and at least one of: at least one of the current value or the voltage value of the at least one magnetoelectric conversion element; or at least one of the current value or the voltage value of the signal processing IC.

### (Item 2)

The estimation apparatus according to item 1, in which the estimation unit estimates the temperature of the circuit board, based on at least one of the current value or the voltage value of the at least one magnetoelectric conversion element and at least one of the current value or the voltage value of the signal processing IC.

### (Item 3)

The estimation apparatus according to item 1, further including a determination unit which determines that an abnormality in the temperature of the circuit board has occurred, when the temperature of the circuit board does not satisfy a predetermined temperature condition.

### (Item 4)

The estimation apparatus according to item 3, in which
the acquisition unit further acquires a current value of a current flowing through the primary conductor, and
the determination unit determines that an overcurrent flows through the primary conductor, when the current value of the primary conductor exceeds a predetermined threshold.

### (Item 5)

The estimation apparatus according to item 1, in which the estimation unit estimates, as the temperature of the circuit board, a temperature in the land portion of the circuit board.

### (Item 6)

The estimation apparatus according to item 1, in which the estimation unit estimates the temperature of the circuit board, based on a predetermined coefficient which is based on a heat transfer characteristic between the at least one magnetoelectric conversion element and the primary conductor and a heat transfer characteristic between the signal processing IC and the primary conductor, at least one of the current value or the voltage value of the at least one magnetoelectric conversion element, and at least one of the current value or the voltage value of the signal processing IC.

### (Item 7)

The estimation apparatus according to item 1, in which the estimation unit estimates an internal temperature of the sealing portion, based on at least one of: at least one of the current value or the voltage value of the at least one magnetoelectric conversion element; or at least one of the current value or the voltage value of the signal processing IC, and a predetermined heat transfer characteristic of the sealing portion, and estimates the temperature of the circuit board, based on the internal temperature of the sealing portion and the predetermined coefficient.

### (Item 8)

The estimation apparatus according to item 3, in which when a rate of change in the temperature, which is estimated, of the circuit board with respect to time is higher than a predetermined rate of change, even if the temperature, which is estimated, of the circuit board does not satisfy the predetermined temperature condition, the determination unit determines that an abnormality in the at least one magnetoelectric conversion element or the signal processing IC has occurred, instead of an abnormality in the temperature of the circuit board.

### (Item 9)

A system including:
the estimation apparatus according to item 1;
a current sensor which includes the at least one magnetoelectric conversion element, the primary conductor and the primary terminal, the signal processing IC, and the sealing portion; and
the circuit board on which the current sensor is mounted.

### (Item 10)

The system according to item 9, in which the current sensor is surface-mounted on the circuit board.

### (Item 11)

The system according to item 9, in which the circuit board is an FR4 circuit board.

### (Item 12)

A current sensor including:
the estimation apparatus according to item 1;
the at least one magnetoelectric conversion element;
the primary conductor and the primary terminal;
the signal processing IC; and
the sealing portion.

### (Item 13)

The current sensor according to item 12, in which the signal processing IC includes the estimation apparatus.

### (Item 14)

A system including:
the current sensor according to item 12;
the circuit board; and
a load which operates when the measurement current is supplied.

### (Item 15)

The system according to item 14, in which
the estimation apparatus
when the temperature of the circuit board estimated by the estimation unit exceeds a first threshold, outputs, to a control unit which controls the load, a first signal indicating that the temperature of the circuit board exceeds the first threshold, and
the first signal includes at least one of an instruction to output an alert signal indicating that the temperature of the circuit board exceeds the first threshold, an instruction to suppress power consumed by the load, an instruction to stop an operation of the load, or an instruction to cool the circuit board.

### (Item 16)

The system according to item 14, in which
the estimation apparatus further includes
an output unit which outputs, when the temperature of the circuit board estimated by the estimation unit exceeds a first threshold, a first signal indicating that the temperature of the circuit board exceeds the first threshold, to a control unit which controls the load, and outputs, when the temperature of the circuit board estimated by the estimation unit exceeds a second threshold higher than the first threshold, a second signal indicating that the temperature of the circuit board exceeds the second threshold, to the control unit.

### (Item 17)

The system according to item 16, in which
the first signal includes an instruction to suppress power consumed by the load, and
the second signal includes an instruction to stop an operation of the load.

### (Item 18)

The system according to item 16, in which the load includes an inverter which supplies power to a motor.

### (Item 19)

The system according to item 14, in which
the circuit board includes a plurality of conductor layers, and
the measurement current flows to the primary terminal and the primary conductor through the plurality of conductor layers.

### (Item 20)

The system according to item 19, in which
the current sensor is a surface-mount type semiconductor package, and
the circuit board includes
a land portion on a primary terminal side which is a conductor portion in contact with the primary terminal of the circuit board, and
at least one of a plurality of through-holes and a plurality of vias, which electrically connect the land portion on the primary terminal side and the plurality of conductor layers, around the land portion on the primary terminal side.

### (Item 21)

The system according to item 20, in which
the at least one of the plurality of through-holes or the plurality of vias are more densely arranged in a region around the land portion on the primary terminal side than in a region around a land portion on a secondary terminal side.

### (Item 22)

An estimation method including:
acquiring at least one of: at least one of a current value of a current output from at least one magnetoelectric conversion element or a voltage value of a voltage applied to the at least one magnetoelectric conversion element; or at least one of a current value of a current or a voltage value of a voltage input to a signal processing IC, in a current sensor including the at least one magnetoelectric conversion element, a primary conductor through which a measurement current measured by the at least one magnetoelectric conversion element flows, and a primary terminal which is electrically connected to the primary conductor, the signal processing IC which processes a signal output from the at least one magnetoelectric conversion element, and a sealing portion which seals the at least one magnetoelectric conversion element, the primary conductor, and the signal processing IC; and
estimating a temperature of a circuit board which includes the current sensor and a land portion in contact with the primary terminal of the current sensor and on which the current sensor is mounted, based on a predetermined coefficient which is based on at least one of a heat transfer characteristic between the at least one magnetoelectric conversion element and the land portion or a heat transfer characteristic between the signal processing IC and the land portion in the circuit board, and at least one of: at least one of the current value or the voltage value of the at least one magnetoelectric conversion element; or at least one of the current value or the voltage value of the signal processing IC.

### Explanation of References

10: current sensor;
20, 22: magnetoelectric conversion element;
30, 108: wire;
130: sealing portion;
140: lead frame;
140a: primary terminal;
140b: primary conductor;
150: lead frame;
150a: secondary terminal;
150b: secondary conductor;
200: circuit board;
201: land portion;
202, 204: conductor layer;
203: land portion;
206: through-hole array;
208: through-hole;
300: estimation apparatus;
310: control unit;
312: acquisition unit;
314: estimation unit;
316: determination unit;
318: output unit;
320: storage unit;
400: electric circuit;
402: control unit; and
100: signal processing IC.

What is claimed is:

1. An estimation apparatus comprising:
an acquisition unit which acquires at least one of: at least one of a current value of a current output from at least one magnetoelectric conversion element or a voltage value of a voltage applied to the at least one magnetoelectric conversion element; or at least one of a current value of a current or a voltage value of a voltage input to a signal processing IC, in a current sensor including the at least one magnetoelectric conversion element, a primary conductor through which a measurement current measured by the at least one magnetoelectric conversion element flows, and a primary terminal which is electrically connected to the primary conductor, the signal processing IC which processes a signal output from the at least one magnetoelectric conversion element, and a sealing portion which seals the at least one magnetoelectric conversion element, the primary conductor, and the signal processing IC; and
an estimation unit which estimates a temperature of a circuit board which includes the current sensor and a land portion in contact with the primary terminal of the current sensor and on which the current sensor is mounted, based on a predetermined coefficient which is based on at least one of a heat transfer characteristic between the at least one magnetoelectric conversion element and the land portion or a heat transfer characteristic between the signal processing IC and the land portion in the circuit board, and at least one of: at least one of the current value or the voltage value of the at least one magnetoelectric conversion element; or at least one of the current value or the voltage value of the signal processing IC.

2. The estimation apparatus according to claim 1, wherein the estimation unit estimates the temperature of the circuit board, based on at least one of the current value or the voltage value of the at least one magnetoelectric conversion element and at least one of the current value or the voltage value of the signal processing IC.

3. The estimation apparatus according to claim 1, further comprising a determination unit which determines that an abnormality in the temperature of the circuit board has occurred, when the temperature of the circuit board does not satisfy a predetermined temperature condition.

4. The estimation apparatus according to claim 3, wherein
the acquisition unit further acquires a current value of a current flowing through the primary conductor, and
the determination unit determines that an overcurrent flows through the primary conductor, when the current value of the primary conductor exceeds a predetermined threshold.

5. The estimation apparatus according to claim 1, wherein the estimation unit estimates, as the temperature of the circuit board, a temperature in the land portion of the circuit board.

6. The estimation apparatus according to claim 1, wherein the estimation unit estimates the temperature of the circuit board, based on a predetermined coefficient which is based on a heat transfer characteristic between the at least one magnetoelectric conversion element and the primary conductor and a heat transfer characteristic between the signal processing IC and the primary conductor, at least one of the current value or the voltage value of the at least one magnetoelectric conversion element, and at least one of the current value or the voltage value of the signal processing IC.

7. The estimation apparatus according to claim 1, wherein the estimation unit estimates an internal temperature of the sealing portion, based on at least one of: at least one of the current value or the voltage value of the at least one magnetoelectric conversion element; or at least one of the current value or the voltage value of the signal processing IC, and a predetermined heat transfer characteristic of the sealing portion, and estimates the temperature of the circuit board, based on the internal temperature of the sealing portion and the predetermined coefficient.

8. The estimation apparatus according to claim 3, wherein when a rate of change in the temperature, which is estimated, of the circuit board with respect to time is higher than a predetermined rate of change, even if the temperature, which is estimated, of the circuit board does not satisfy the predetermined temperature condition, the determination unit determines that an abnormality in the at least one magnetoelectric conversion element or the signal processing IC has occurred, instead of an abnormality in the temperature of the circuit board.

9. A system comprising:
the estimation apparatus according to claim 1;
a current sensor which includes the at least one magnetoelectric conversion element, the primary conductor and the primary terminal, the signal processing IC, and the sealing portion; and
the circuit board on which the current sensor is mounted.

10. The system according to claim 9, wherein the current sensor is surface-mounted on the circuit board.

11. The system according to claim 9, wherein the circuit board is an FR4 circuit board.

12. A current sensor comprising:
the estimation apparatus according to claim 1;
the at least one magnetoelectric conversion element;
the primary conductor and the primary terminal;
the signal processing IC; and
the sealing portion.

13. The current sensor according to claim 12, wherein the signal processing IC includes the estimation apparatus.

14. A system comprising:
the current sensor according to claim 12;
the circuit board; and
a load which operates when the measurement current is supplied.

15. The system according to claim 14, wherein
the estimation apparatus
when the temperature of the circuit board estimated by the estimation unit exceeds a first threshold, outputs, to a control unit which controls the load, a first signal indicating that the temperature of the circuit board exceeds the first threshold, and
the first signal includes at least one of an instruction to output an alert signal indicating that the temperature of the circuit board exceeds the first threshold, an instruction to suppress power consumed by the load, an instruction to stop an operation of the load, or an instruction to cool the circuit board.

16. The system according to claim 14, wherein
the estimation apparatus further includes
an output unit which outputs, when the temperature of the circuit board estimated by the estimation unit exceeds a first threshold, a first signal indicating that the temperature of the circuit board exceeds the first threshold, to a control unit which controls the load, and outputs, when the temperature of the circuit board estimated by the estimation unit exceeds a second threshold higher than the first threshold, a second signal indicating that the temperature of the circuit board exceeds the second threshold, to the control unit.

17. The system according to claim 16, wherein
the first signal includes an instruction to suppress power consumed by the load, and
the second signal includes an instruction to stop an operation of the load.

18. The system according to claim 16, wherein the load includes an inverter which supplies power to a motor.

19. The system according to claim 14, wherein
the circuit board includes a plurality of conductor layers, and
the measurement current flows to the primary terminal and the primary conductor through the plurality of conductor layers.

20. The system according to claim 19, wherein
the current sensor is a surface-mount type semiconductor package, and
the circuit board includes
a land portion on a primary terminal side which is a conductor portion in contact with the primary terminal of the circuit board, and
at least one of a plurality of through-holes and a plurality of vias, which electrically connect the land portion on the primary terminal side and the plurality of conductor layers, around the land portion on the primary terminal side.

21. The system according to claim 20, wherein
the at least one of the plurality of through-holes or the plurality of vias are more densely arranged in a region around the land portion on the primary terminal side than in a region around a land portion on a secondary terminal side.

22. An estimation method comprising:
acquiring at least one of: at least one of a current value of a current output from at least one magnetoelectric conversion element or a voltage value of a voltage applied to the at least one magnetoelectric conversion element; or at least one of a current value of a current or a voltage value of a voltage input to a signal processing IC, in a current sensor including the at least one magnetoelectric conversion element, a primary conductor through which a measurement current measured by the at least one magnetoelectric conversion element flows, and a primary terminal which is electrically connected to the primary conductor, the signal processing IC which processes a signal output from the at least one magnetoelectric conversion element, and a sealing portion which seals the at least one magnetoelectric conversion element, the primary conductor, and the signal processing IC; and
estimating a temperature of a circuit board which includes the current sensor and a land portion in contact with the primary terminal of the current sensor and on which the current sensor is mounted, based on a predetermined coefficient which is based on at least one of a heat transfer characteristic between the at least one magnetoelectric conversion element and the land portion or a heat transfer characteristic between the signal processing IC and the land portion in the circuit board, and at least one of: at least one of the current value or the voltage value of the at least one magnetoelectric conversion element; or at least one of the current value or the voltage value of the signal processing IC.
